(19) United States
(12) Patent Application Publication
(10) Pub. No.: US 2026/0133471 A1
(43) Pub. Date: May 14, 2026

(54) PROTECTION DEVICE, DETECTION SYSTEM, AND A METHOD THEREFOR

(71) Applicant: VON ARDENNE Asset GmbH & Co. KG, Dresden (DE)

(72) Inventors: Michael HOFMANN, Dresden (DE); Torsten DSAAK, Dresden (DE); Steffen LESSMANN, Dresden (DE)

(21) Appl. No.: 19/385,702

(22) Filed: Nov. 11, 2025

(30) Foreign Application Priority Data
Nov. 11, 2024 (DE) 10 2024 132 765.0

(51) Int. Cl. G03B 11/04; C23C 14/52

(52) U.S. Cl. CPC G03B 11/045; C23C 14/52

(57) ABSTRACT

According to various embodiments, a protection device comprises: a first housing component and a second housing component, which are configured to be inserted into each other to form a pressure housing, in which a cavity for receiving an optical sensing device is provided; wherein the first housing component comprises a transparent light-receiving region which is adjacent to the cavity; a mounting device opposite the light-receiving region for mounting one or more fluid conduits to the pressurized housing; a first fluid transfer channel and a second fluid transfer channel, each fluid transfer channel fluidically coupling the cavity to the mounting device or opening into the mounting device.

### CROSS-REFERENCE TO RELATED APPLICATION

This application claims priority pursuant to 35 U.S.C. 119(a) to German Application No. 102024132765.0, filed November 11, 2024, which application is incorporated herein by reference in its entirety.

### FIELD OF THE INVENTION

Various embodiments relate to a protection device, a detection system, and a method therefor.

### BACKGROUND

In general, a substrate may be treated (processed) in a vacuum, e.g., coated, so that the chemical and/or physical properties of the substrate may be changed. Various coating processes may be carried out to coat a substrate, of which physical vapor deposition (PVD) is an established representative. For example, a vacuum coating system may be used to deposit one or more layers on one or more substrates by chemical and/or physical vapor deposition.

In this process, various areas in the vacuum may be difficult to access and/or exposed to operating conditions that are hostile to the equipment. If such an area is to be monitored visually, e.g., to provide image information, the camera used for this purpose often fails, is expensive, requires too much installation space, and/or cannot adequately cover the area. An example of this is the hard-to-access maintenance valve, for which it may be of interest to know whether a substrate is located in the substrate transfer opening (also known as the passage slot). This applies analogously to other areas of a machine that are not necessarily exposed to a vacuum.

Various embodiments provided herein address this dilemma. According to various embodiments, a protection device, a detection system, and a use thereof are provided which facilitate optical detection in an area that is difficult to access and/or in operating conditions that are hostile to operation. For this purpose, reference is made to an area in which a vacuum is formed, whereby the description herein may be applied analogously to any other area, e.g., areas that are difficult to access and/or operating conditions that are hostile to operation, examples of which include: a corrosive atmosphere, overpressure, dust (e.g., abrasion), or a coating material from a coating process.

According to various embodiments, the protection device has a small footprint due to its compact design and offers protection against operating conditions that are hostile to operation. Among other things, this makes it possible to position an optical sensing device closer to the area to be detected, e.g., in a vacuum and/or exposed to a coating process. This improves access compared to a conventional chamber window provided in a chamber wall of a vacuum chamber. Compared to the chamber window, for example, the scope for viewing and the perspective (the viewing angle) are increased.

Furthermore, the sensing device is effectively protected against the environmental conditions, which means that it does not necessarily have to be vacuum-compatible, may be cooled more effectively, and may be positioned closer to the source of harmful environmental conditions. In particular, the service life of the sensing device is increased and requirements (e.g., for temperature resistance and/or dust tightness) on it are reduced, making it more cost-effective.

Various examples are described below that relate to what is described herein and shown in the figures.

Example 1 is configured in accordance with one of the attached claims and/or is a protection device, preferably (e.g., configured as a camera protection device) for an optical (e.g., optoelectronic) component (e.g., a sensing device, in particular a camera), comprising: a first housing component and a second housing component, which are configured to be inserted into one another to form a pressurized housing in which a cavity (also referred to as a receiving space) is provided for receiving the component (e.g., the sensing device); wherein the first housing component includes a transparent light-receiving region (also referred to as a viewing area) which adjoins the cavity (along a sensing direction); a mounting device (also referred to as a fluid mounting device) opposite the light-receiving region for mounting (e.g., coupling device for coupling) one or more than one fluid conduit (e.g., to the overpressure housing); one or more fluid transfer channels (e.g., comprising a first fluid transfer channel, a second fluid transfer channel, and/or a third fluid transfer channel), each fluid transfer channel fluidically coupling the cavity to the mounting device (e.g., an opening thereof) or opening into the mounting device.

Example 2 (e.g., a protection device) is configured according to Example 1, wherein the first housing component and/or the second housing component are tubular and/or penetrated by a through opening.

Example 3 (e.g., a protection device) is configured according to Example 1 or 2, wherein the second housing component is configured to be inserted into the first housing component (e.g., a through opening thereof), e.g., towards the light-receiving region.

Example 4 (e.g., a protection device) is configured according to examples 1 to 3, a first sealing device which surrounds and/or seals the light-receiving region.

Example 5 The light-receiving device (e.g., a protection device) is configured according to one of examples 1 to 4, wherein the mounting device includes a hose connection (e.g., hose nozzle) into which the first fluid transfer channel opens (or which provides at least a section of the first fluid transfer channel) and/or which protrudes from the second housing component.

Example 6 (e.g., a protection device) is configured according to one of examples 1 to 5, wherein the mounting device includes a flange and/or an (e.g., tubular) intermediate piece into which the first and/or second fluid transfer channel opens and/or includes a through opening for receiving the hose connection. This (e.g., the intermediate piece) facilitates assembly.

Example 7 (e.g., a protection device) is configured according to examples 1 to 6, wherein the mounting device includes an (e.g., tubular) intermediate piece which includes a flange and a second sealing device opposite the flange for coupling to the overpressure housing (e.g., the first or second housing component). This (e.g., the intermediate piece) facilitates assembly.

Example 8 (e.g., a protection device) is configured according to one of examples 1 to 7, wherein the second housing component includes a holding device which is configured to hold the sensing device (e.g., camera), preferably in a rotationally secure manner (e.g., by force and/or form fit).

Example 9 (e.g., a protection device) is configured according to examples 1 to 8, wherein the first and/or second fluid transfer channel opens into the cavity; and/or wherein the third fluid channel fluidically couples two sections of the cavity (between which, for example, the holding device is arranged), e.g., past the holding device. The third fluid channel promotes fluid flow.

Example 10 (e.g., a protection device) is configured according to one of examples 1 to 9, wherein the second housing component includes a first recess on the front side, by which the first fluid transfer channel is provided, includes a groove-shaped second recess, by which the second fluid transfer channel is provided; and/or a groove-shaped third recess, by which the third fluid transfer channel is provided.

Example 11 (e.g., a protection device) is configured according to one of examples 1 to 10, wherein the mounting device includes a circumferential sealing surface and/or a flange.

Example 12 (e.g., a protection device) is configured according to one of examples 1 to 11, wherein the first housing component includes a first recess for receiving the second housing component, which: adjoins the opening; provides at least one area of the cavity; and/or tapers toward the light-receiving region (also referred to as the light transfer area). This (e.g., the tapering geometry) simplifies construction and assembly.

Example 13 (e.g., a protection device) is configured according to one of examples 1 to 12, wherein the second housing component includes a recess into which the first fluid transfer channel opens and/or past which the second fluid channel runs. This promotes fluid flow and thus cooling. The recess may, for example, taper toward the mounting device and/or provide at least one area of the cavity. This (e.g., the tapering geometry) simplifies the design and assembly.

Example 14 (e.g., a protection device) is configured according to one of examples 1 to 13, further comprising: a transparent wall (e.g., plate, e.g., pane) which preferably abuts the first sealing device and/or provides at least a portion of the light-receiving region.

Example 15 (e.g., a protection device) is configured according to one of examples 1 to 14, further comprising: a cover flap which is movably mounted (e.g., by a pivot bearing) so that the light-receiving region is covered by the cover flap when the cover flap is brought into a first state (e.g., position) and is exposed when the cover flap is brought into a second state (e.g., position). position), is covered by the cover flap, and when the cover flap is moved to a second state (e.g., position), is exposed.

Example 16 (e.g., a protection device) is configured according to Examples 1 to 15, further comprising: a gear mechanism which is configured to convert a force acting on the gear mechanism into a torque and to transmit the torque to the cover flap. The gear mechanism may, for example, comprise one or more levers and/or a Bowden cable.

Example 17 is a detection system comprising: a protection device according to one of claims 1 to 16, the sensing device, which is received in the cavity and/or held by the holding device (e.g., secured against rotation), wherein the sensing device comprises, for example, a camera (e.g., endoscope camera) and/or an optical fiber cable.

Example 18 is the use of one of examples 1 to 17 in a vacuum for detecting optical radiation (at least in the vacuum), preferably for detecting image information, e.g., of a process (e.g., coating process) and/or a substrate transfer opening, e.g., when the protection device is exposed to the process and/or a vacuum.

Example 19 (e.g., a use) is configured according to one of examples 1 to 18, wherein the component includes (e.g., consists) of a (e.g., optical) sensing device, which is configured, for example, to detect optical radiation.

Example 20 is configured according to one of examples 1 to 19, wherein the component comprises or consists of a camera (e.g., an endoscope head) which is configured, for example, to detect optical radiation.

Example 21 is configured according to one of examples 1 to 20, wherein the component is configured to detect electromagnetic (e.g., optical) radiation, e.g., in a wavelength range from approximately 10E-8 m to approximately 10E-5 m.

Example 22 is a vacuum arrangement comprising: a vacuum chamber in which the protection device according to one of examples 1 to 21 is arranged.

Example 23 is configured according to one of examples 1 to 22, wherein the sensing device comprises one or more optical sensors.

Example 24 is configured according to one of examples 1 to 23, wherein a temperature (also referred to as operating temperature) to which the protection device is exposed during operation is greater than 100°C (e.g., 200°C or 300°C).

Example 25 is configured according to one of examples 1 to 24, wherein a chemical composition of an atmosphere (also referred to as a process atmosphere) to which the protection device is exposed during operation comprises a metal, a semiconductor, and/or a transition metal.

Example 26 is configured according to one of examples 1 to 25, wherein the protection device is exposed to a vacuum during operation.

Example 27 is configured according to one of examples 1 to 26, wherein the protection device is exposed to a coating process during operation.

Example 28 is configured according to one of examples 1 to 27, wherein the protection device is exposed during operation to a material with which the protection device is coated.

Example 29 is configured according to one of examples 1 to 28, wherein the sensing device and/or the receiving chamber are exposed during operation to a fluid, e.g., a liquid, which flows through one or more fluid channels, for example.

Example 30 is configured according to one of examples 1 to 29, wherein the sensing device is configured to detect a wavelength or a spectral range for which the light reception area is transparent.

Example 31 is configured according to one of examples 1 to 30, (e.g., the sensing device) further comprising a (e.g., multi-part and/or hermetically separating) enclosure (e.g., comprising one or more than one third housing component), which is configured to be received in the cavity and to enclose an optical sensor (or a camera) (e.g., to enclose it in a watertight manner), the enclosure preferably comprising.

Example 32 is configured in accordance with one of examples 1 to 31, (e.g., the sensing device, e.g., its enclosure) further comprising: a plurality of third housing components which, when joined together, form a cavity (also referred to as an intermediate space) for receiving an optical sensor (or a camera) and/or an additional (e.g., at least partially transparent) light-receiving wall which delimits the intermediate space and, when the third housing components are arranged in the receiving space, faces the light-receiving region.

Example 33 is configured according to one of examples 1 to 32, (e.g., the sensing device, e.g., its housing) further comprising: a feed-through (e.g., cable feed-through) which is configured to receive (e.g., seal) a hose (e.g., of the cable), wherein the feed-through has, for example, a sealing device (e.g., comprising a ring seal). The hose can, for example, provide an electrical sheathing for the cable or be configured to receive the cable.

Example 34 is configured according to one of examples 1 to 33, (e.g., the sensing device) further comprises: an optical sensor and a printed circuit board which communicatively couples the sensor to a cable (e.g., its electrical conductors). Furthermore, the sensing device may, for example, comprise a (e.g., rigid) carrier on which the printed circuit board and/or the sensor are mounted.

Example 35 is configured according to one of examples 1 to 34, wherein the second housing component is configured to be inserted into the first housing component (e.g., along a direction, e.g., the sensing direction), and/or wherein the first housing component includes a recess, which preferably extends along the direction (e.g., sensing direction) into the first housing component, for receiving the second housing component.

Example 36 is configured according to one of examples 1 to 35, wherein the transparent light-receiving region adjoins the cavity along a direction (e.g., sensing direction); and/or wherein the first fluid transfer channel opens into the cavity along the direction (e.g., sensing direction).

Example 37 is configured according to one of examples 1 to 36, wherein the light-receiving region of the mounting device is arranged opposite along a direction (e.g., sensing direction).

Example 38 is configured according to one of examples 1 to 37, wherein: the second fluid transfer channel (e.g., along the direction) includes a greater extent (e.g., length) than the first fluid transfer channel (at least more than twice, e.g., three times that of the latter) and/or the second fluid transfer channel (e.g., along the direction) extends past one or more of: an opening of the first fluid transfer channel in the cavity and/or a section of the cavity (into which the first fluid transfer channel opens, for example).

Example 39 is configured according to one of examples 1 to 38, wherein the cavity includes a section which separates the first fluid transfer channel and the second fluid transfer channel from each other (into which they preferably open); and/or wherein the section has an extension (e.g., length and/or along the direction) that is greater than one or more of the following: an extension (e.g., width) of the cavity transverse to the direction; the extension of the first fluid transfer channel (e.g., along the direction).

Example 40 is configured according to one of Examples 1 to 39, wherein the overpressure housing is configured to receive an overpressure in the cavity (e.g., relative to an external pressure to which the overpressure housing is exposed). The overpressure has, for example, a difference from the external pressure of more than 0.5 bar, e.g., more than 0.9 bar.

Example 41 is configured according to one of examples 1 to 40, wherein the overpressure housing is configured geometrically stable regarding an overpressure in the cavity (e.g., relative to an external pressure to which the overpressure housing is exposed). The overpressure has, for example, a difference from the external pressure of more than 0.5 bar, e.g., more than 0.9 bar.

Example 42 is configured according to one of examples 1 to 41, wherein the first fluid transfer channel and the second fluid transfer channel are configured to guide a fluid through the cavity (e.g., a section thereof) and/or to exchange the fluid with each other by the cavity (e.g., a section thereof).

Example 43 is configured according to one of examples 1 to 42, wherein the first housing component and/or the second housing component are metallic and/or comprise at least one metal, e.g., consist thereof.

Example 44 is configured according to one of examples 1 to 43, wherein the first housing component and/or the second housing component are (e.g., mechanically and/or chemically) stable at a temperature of 150°C or more, e.g., 200°C or more, e.g., 300°C or more, e.g., 500°C or more.

### BRIEF DESCRIPTION OF THE DRAWINGS

Various embodiments are disclosed, by way of example only, with reference to the accompanying schematic drawings in which corresponding reference symbols indicate corresponding parts, in which:

FIGS. 1A and 1B each show a protection device according to different embodiments in different schematic views;

FIGS. 2A and 2B each show a detection system according to different embodiments in different schematic views;

FIG. 3A shows a supply system of the detection system according to different embodiments in a schematic side view or cross-sectional view;

FIGS. 3B and 4A each show a vacuum arrangement according to different embodiments in different schematic views;

FIGS. 4B and 5A each show a vacuum arrangement according to different embodiments in different schematic views;

FIG. 5B shows a hose system according to various embodiments in a schematic cross-sectional view;

FIG. 6 shows a protection device according to various embodiments in a schematic view; and,

FIGS. 7A and 7B each show a detection system according to different embodiments in different schematic views.

### DETAILED DESCRIPTION OF THE INVENTION

The following detailed description refers to the accompanying drawings, which form part of this specification and in which specific embodiments are shown for illustrative purposes in which the invention may be practiced. In this regard, directional terminology such as "top," "bottom," "front," "back," "front," "rear," etc. is used with reference to the orientation of the figure(s) described. Since components of embodiments may be positioned in several different orientations, the directional terminology is for illustrative purposes only and is in no way limiting. It will be understood that other embodiments may be used and structural or logical changes may be made without departing from the scope of the present invention. It is understood that the features of the various exemplary embodiments described herein may be combined with each other, unless specifically stated otherwise. The following detailed description is therefore not to be construed in a limiting sense, and the scope of protection of the present invention is defined by the appended claims. The expression 10Ex (where x is a number) expresses the value 10^{x} (10 to the power of x).

In this description, the terms "connected," "connected to," and "coupled" are used to describe both a direct and an indirect connection (e.g., ohmic and/or electrically conductive, e.g., an electrically conductive connection), a direct or indirect connection, and a direct or indirect coupling. In the figures, identical or similar elements are given identical reference symbols where appropriate.

According to various embodiments, the term "coupled" or "coupling" may be understood in the sense of a (e.g., mechanical, hydrostatic, thermal, and/or electrical), e.g., direct or indirect, connection and/or interaction. For example, several elements may be coupled together along an interaction chain along which the interaction may be exchanged, e.g., a fluid (then also referred to as fluid-conducting coupled). For example, two elements coupled together may exchange an interaction with each other, e.g., a mechanical, hydrostatic, thermal, and/or electrical interaction. A coupling of several vacuum components (e.g., valves, pumps, chambers, etc.) with each other may mean that they are fluidically coupled with each other. According to various embodiments, "coupled" may be understood in the sense of a mechanical (e.g., physical) coupling, e.g., by direct physical contact. A coupling may be configured to transmit a mechanical interaction (e.g., force, torque, etc.).

The term "vacuum pressure" herein refers to a negative pressure in the vacuum range (i.e., a pressure of less than 0.3 bar), e.g., a pressure in a range of approximately 10 mbar to approximately 1 mbar (in other words, rough vacuum) or less, e.g., a pressure in a range of approximately 1 mbar to approximately 10⁻³ mbar (in other words, fine vacuum) or less, e.g., a pressure in the range of approximately 10⁻³ mbar to approximately 10⁻⁷ mbar (in other words, high vacuum) or less, e.g., a pressure less than high vacuum, e.g., less than approximately 10⁷ mbar (also referred to as 10E⁻7 mbar).

A cavity may be understood here, for example, as a contiguous cavity that is free of solid material. The cavity may be filled with a fluid, e.g., a liquid and/or a gas.

According to various embodiments, the vacuum chamber may be provided by a chamber housing (also referred to as a vacuum chamber housing) in which one or more chambers may be provided. The vacuum chamber housing can, for example, be coupled to a pump arrangement, e.g., a vacuum pump arrangement, (e.g., gas-conducting) to provide a negative pressure or a vacuum, and be configured to be stable in such a way that it may withstand the effects of air pressure in the pumped-out state (when a vacuum pressure is provided therein). This applies analogously to the seals. The pump arrangement (comprising at least one vacuum pump, e.g., a high vacuum pump, e.g., a turbomolecular pump) may enable part of the gas to be pumped out of the interior of the processing chamber, e.g., from the processing space. Accordingly, one or more vacuum chambers may be provided in a vacuum chamber housing. Furthermore, a vacuum chamber equipped for processing is also referred to as a processing chamber, e.g., in the case of coating as an exemplary processing as a coating chamber.

According to various embodiments, an overpressure chamber (shorter also referred to as pressure chamber) may be provided by a chamber housing (also referred to as a pressure chamber housing), in which one or more chambers may be provided. The pressure chamber housing can, for example, be configured to provide a pressure in such a stable manner that it may withstand the effect of the pressure inside the chamber. For example, the overpressure chamber housing in which air pressure is provided may be arranged in a vacuum so that the air pressure acts as overpressure relative to the vacuum. Air pressure is understood to be the hydrostatic pressure of the Earth's atmosphere at the location of the overpressure chamber.

A sensor (also referred to as a detector) may be understood as a transducer that is configured to qualitatively or quantitatively detect a property of its environment corresponding to the sensor type, e.g., a physical or chemical property and/or a material characteristic. The measured variable is the physical quantity that is measured by the sensor. Depending on the complexity of the environment to be measured, the sensor may be configured to distinguish between only two states of the measured variable (also referred to as a measuring switch), between more than two states of the measured variable, or to record the measured variable quantitatively. The measuring switch can, for example, distinguish whether the measured variable meets a criterion (e.g., exceeds or falls below a threshold value) or does not meet the criterion. An example of a measuring switch is a pressure sensor that is configured to detect whether a pressure as a measured variable is a negative pressure or not. Another example of a measuring switch is a level sensor that is configured to detect whether a level as a measured variable has reached the location of the sensor or not, e.g., by detecting whether it is in contact with water or not. An example of a quantitatively detected measured variable is, for example, a fluid flow rate (e.g., flow rate), whose actual state may be detected as a value by the sensor.

A sensor may be part of a measuring chain that has a corresponding infrastructure (e.g., processor, storage medium, and/or bus system or the like). The measuring chain may be configured to control the corresponding sensor (e.g., water sensor, pressure sensor, and/or optical sensor), to process the measured variable detected by the sensor as an input variable, and based on this, to provide an electrical signal as an output variable that represents the input variable. The measuring chain can, for example, be implemented by the control device.

A sensing device (also referred to as a sensor device or measuring element) has, for example, one or more sensors (e.g., image detection sensor) per measured variable of the sensing device, which is configured to detect one or more measured variables (e.g., wavelength and/or intensity of electromagnetic radiation) of the sensing device and/or to cover a measurement range of the measured variable. The electromagnetic radiation may have a wavelength range that includes X-rays, UV radiation (A to C), visible light, and/or infrared radiation (A to C).

An image capture sensor (also referred to as an image sensor or optical sensor) may have one or more photoelectrically active areas (also referred to as pixels) which, for example, generate and/or modify an electrical signal in response to electromagnetic radiation (e.g., light, e.g., visible light). The image sensor may, for example, comprise or be formed from a CCD sensor (charge-coupled device sensor) and/or an active pixel sensor (also referred to as a CMOS sensor). Optionally, an image capture sensor may be configured to be wavelength-sensitive (e.g., for capturing color information), e.g., by several color filters (e.g., in grid form).

Transparent is understood here as having a transmission coefficient of more than 50%, e.g., for electromagnetic radiation (e.g., for a wavelength of 550 nanometers) and/or more than 75%, e.g., 90%.

An endoscope camera includes a (e.g., flexible or rigid) cable and a so-called head (also referred to as an endoscope head), which includes a light source and a camera. The endoscope head may, for example, have a waterproof housing in which the light source and the camera are arranged and/or which is connected to the cable sheathing in a waterproof manner. The camera has, for example, an image capture sensor and upstream optics (e.g., comprising one or more lenses).

Reference is made here to a multi-part housing (e.g., overpressure housing) which includes several components (also referred to as housing parts) that may be assembled to form the housing. The housing includes a receiving space, which may be provided at least in sections by one or more of the housing components. For example, a housing component may have a recess (e.g., a through-opening) which provides at least one section of the receiving space. Alternatively, or additionally, the recess may be configured to receive one of the other housing components. The multiple housing components may have one or more wall-forming housing components, which provide a wall of the housing (also referred to as a housing wall), e.g., at least a section of the housing wall. Two housing components inserted into each other may touch each other, e.g., with their surfaces. For example, one of the housing components may have an outer surface that rests against an inner surface of another of the housing components when the housing is assembled.

A mounting device is understood herein to be a device which is configured for mounting, for example for mounting on a complementary mounting device (also referred to as a counter-mounting device). During mounting, several components are connected (e.g., rigidly) to each other by their mounting devices. Mounting may be (for example exclusively) form-fitting and/or detachable. The mounting device may preferably have a (e.g., planar) mounting surface which, during mounting, rests against a complementary mounting surface of the counter-mounting device and/or provides a seal. The mounting device may, for example, have one or more (e.g., integral) mounting profiles (e.g., form-fitting profiles), which are provided, for example, by an unevenness (e.g., protrusion or recess) of the mounting device. Examples of the mounting profile include: a thread, a groove (e.g., for receiving a key and/or dovetail groove), a locking tab, a bayonet lock, a pin, etc. Examples of the unevenness include: an opening (e.g., through hole and/or threaded hole), a bolt (e.g., a threaded bolt).

An exemplary implementation of the mounting device is configured as a flange, e.g., as a vacuum flange. The flange may be configured for rigid and/or detachable connection to another flange. Two flanges connected to each other form a so-called flange connection. The flange may have a (e.g., planar) mounting surface. Optionally, the flange may be penetrated by an opening (also referred to as a flange opening) which is surrounded by the mounting surface, e.g., along a closed path. The flange connection may feature two flanges with their mounting surfaces facing each other, e.g., touching each other and/or pressed against each other. The flange opening of a housing may open into the interior of the housing, e.g., adjacent to it. Optionally, the flange may have a groove surrounding the flange opening, e.g., along the closed path surrounding the flange opening, and/or adjacent to the mounting surface. A seal may optionally be received in the groove, examples of which include: a ring seal, a metal seal, and/or a plastic seal. Optionally, the flange may have a collar-shaped projection that includes the mounting surface. For example, the mounting surface may protrude.

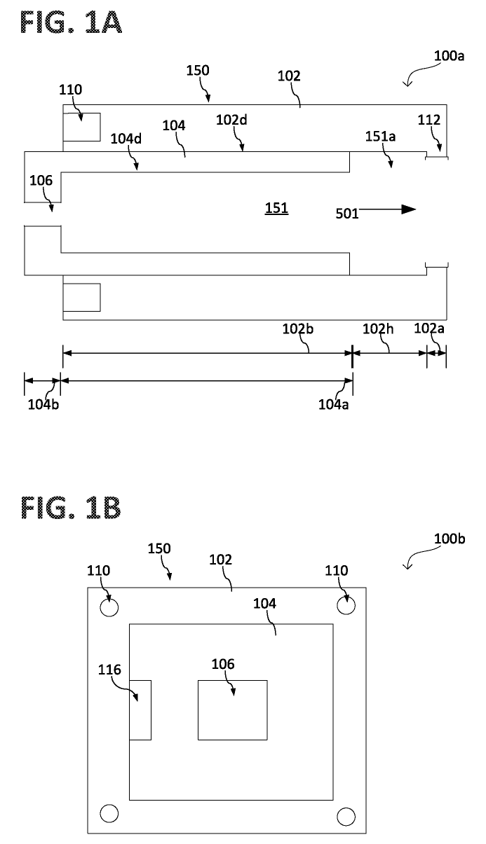

FIG. 1A illustrates a protection device according to various embodiments 100a in a schematic side view or cross-sectional view, for example, configured according to example 1 and/or used according to example 18. The protection device includes two housing components that may be inserted into each other along direction 501 (also referred to as the sensing direction), which, when inserted together, form an overpressure housing 150 in which the receiving space 151 is provided. The two housing components 102, 104 comprise a first housing component 102 (also referred to as the outer part 102) and a second housing component 104 (also referred to as the inner part 104).

An exemplary implementation of the outer part 102 (preferably according to example 2) includes (e.g., or comprises) a tube. Alternatively, or additionally, the outer part 102 (e.g., the tube) is penetrated along a sensing direction 501 by a through opening 102d (also referred to as an outer opening), which provides, for example, a tapered recess. The outer part 102 includes one or more housing walls which bound the outer opening 102d. For example, the outer part 102 includes a first end face and/or a second end face opposite the first end face, at which the outer opening 102d is exposed.

An exemplary implementation of the inner part 104 (preferably according to example 3) is configured to be inserted into the receiving opening 102d, e.g., in the sensing direction 501. The inner part 104 (preferably according to example 2) has, for example, a tube or consists of it. Alternatively, or additionally, the inner part 104 (e.g., the tube) is penetrated along the sensing direction 501 by a through opening 104d (also referred to as an inner opening), which provides, for example, a fluid channel 106 and/or a tapered recess. The inner part 104 includes one or more housing walls which bound the inner opening 102d. For example, the inner part 104 includes a first end face and/or a second end face opposite the first end face, at which the outer opening 102d is exposed.

An exemplary implementation of the outer opening 102d includes several sections disposed one after the other along the sensing direction 501, of which a first section 102a (also referred to as the front viewing opening) at least partially provides the transparent light-receiving region 112, a second section 102b receives the inner part 104, and an optional third section 102h (also referred to as the overflow section) provides an area of the receiving space 151.

An exemplary implementation of the inner opening 104d includes several sections disposed one after the other along the sensing direction 501, of which a first section 104a provides an area of the receiving space 151 (and, when assembled, faces the light-receiving region 112, for example), and a second section 104b provides an (e.g., inner) fluid transfer channel 106 at least in sections.

An exemplary implementation of the transparent light-receiving region 112 includes the front viewing opening 102a. Alternatively, or additionally, the light-receiving region 112 includes a transparent housing wall (not shown, also referred to as a light-receiving wall) or at least a section thereof. The light-receiving wall has, for example, glass and/or a plate or consists of these. The light-receiving wall can, for example, delimit or at least cover the viewing opening 102a. A sealing device (also referred to as a light-receiving seal) may optionally be arranged between the light-receiving wall and the outer part 102. The light-receiving wall and/or the light-receiving seal may, for example, be received in a recess in the outer part 102.

An exemplary implementation of the fluid mounting device 110 includes one or more flanges, which, for example, have one or more mounting openings and/or a sealing device. The mounting device 110 (or at least one flange thereof) may be monolithically connected to the outer part 102 or mounted thereon in a form-fitting manner (e.g., clamped and/or screwed), as explained in more detail below. Alternatively, or additionally, the mounting device 110 may be multi-part.

FIG. 1B illustrates a protection device according to various embodiments 100b in a schematic side view or cross-sectional view with a view along the sensing direction 501, e.g., configured according to embodiments 100a and/or according to Example 1.

An exemplary implementation of the protection device includes a first fluid transfer channel 106 (also referred to as an inner fluid transfer channel 106) that opens into the second section 104b of the inner opening 104d and/or extends along the sensing direction 501. Alternatively, or additionally, the protection device includes a second fluid transfer channel 116 (also referred to as an outer fluid transfer channel 116) which is adjacent to an inner surface of the outer part 102 against which the inner part 104 rests and/or which opens into the overflow section 102h and/or extends along the sensing direction 501.

For example, the inner part 104 and/or the outer part 102 may have a groove as a (e.g., channel-shaped) recess, which provides the second fluid transfer channel 116 and/or extends along the sensing direction 501. For example, the groove may be formed between the outer wall of the inner part 104 and the inner wall of the outer part 102, which are joined together.

An exemplary implementation of the second fluid transfer channel 116 is provided at least in sections by a channel-shaped groove of the inner part 104, which extends in the sensing direction. Alternatively, or additionally, the outer part 102 includes a channel-shaped groove (not shown) which extends in the sensing direction and at least partially provides the second fluid transfer channel 116.

Exemplary aspects of the protection device are explained below using a detection system that comprises the protection device and a sensing device, whereby the description herein may be applied analogously to the protection device as such (e.g., if it is provided individually).

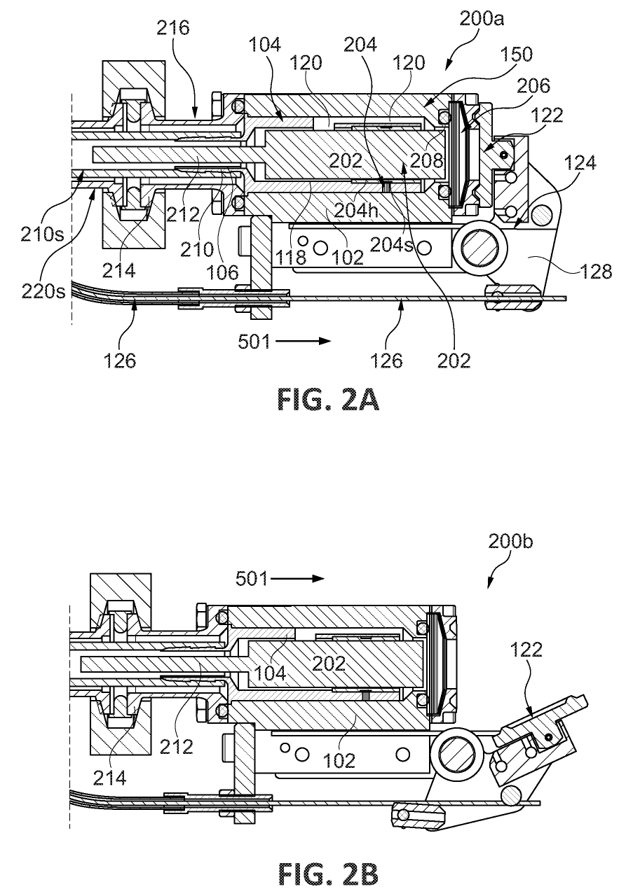

FIG. 2A illustrates a detection system according to various embodiments 200a in a schematic side view or cross-sectional view, which comprises the protection device, e.g., according to one of the embodiments 100a to 100b and/or according to example 1.

An exemplary implementation of the sensing device includes a camera 202 as a cylindrical end section (also referred to as a head), which is configured to detect optical radiation, e.g., light, originating from the sensing direction 501. Camera 202 is arranged in the recording room and/or mounted by a holding device 204 (then also referred to as a camera holding device). The camera holding device 204 is, for example, configured to hold the camera head in a force-fit manner.

For ease of understanding, reference is made here to the camera 202 of the sensing device, which allows for a particularly cost-effective implementation. It may be understood that the sensing device may also have an optical fiber, which is led out of the overpressure housing 150 through the internal fluid transfer channel. The light guide provides a light-conducting coupling between the camera, which then does not necessarily have to be located in the recording room, and the light-receiving region. The light guide facilitates the proximity of the light-receiving region to a process that would otherwise interfere with the operation of the camera (e.g., due to heat and/or high-frequency electromagnetic radiation).

An exemplary implementation of the camera holding device 204 includes a clamping screw 204s and/or a retaining sleeve 204h. The clamping screw 204s can, for example, be received in a threaded bore in the inner part 104, which opens into the first section 104a of the inner opening 104d. The retaining sleeve 204h is arranged, for example, in the first section 104a of the inner opening 104d, whereby the camera 202 is arranged in the retaining sleeve and the clamping screw presses against the retaining sleeve to mount the camera 202 in a force-fit manner.

The retaining sleeve 204h protects the camera 202, but may also be omitted. Alternatively, or additionally, the retaining sleeve 204h provides a gap 118 between the sensing device (e.g., camera) and the inner surface of the inner part 104, which promotes cooling of the sensing device. For example, the retaining sleeve 204h may provide or create a gap 118 (also referred to as a fluid gap) between the sensing device and the inner surface of the inner part 104.

By the force-fit mounting of the camera 202 using the camera holding device 204 (preferably according to example 8), e.g., by the clamping screw, the camera 202 may be held in a rotationally fixed position. Alternatively, or additionally, the camera holding device 204 and the camera 202 may interlock to provide the rotation lock. The rotation lock locks the alignment and/or location of the camera in the inner part 104 so that the image information captured with it is positionally stable.

Furthermore, the capture device includes a cable 212 (e.g., camera cable) which includes one or more electrical lines, e.g., data line and/or power supply line, and/or an optical fiber cable. The cable 212 protrudes from the inner part 104, e.g., through the (e.g., inner) fluid transfer channel 106.

An exemplary implementation (preferably according to Example 5) of the first sealing device 208 (then also referred to as a light-receiving seal) includes a ring seal which surrounds the light-receiving region, or at least the front viewing opening 102a. The ring seal is received in a sealing groove of the outer part 102, which surrounds the light-receiving region, or at least the front viewing opening 102a.

An exemplary implementation of the transparent light-receiving wall is provided, at least in sections, by a sight glass 206. The sight glass 206 may be received in a form-fitting manner in a recess formed between two mounting devices of the outer part 102 (also referred to as glass mounting devices), which form, for example, a frame (e.g., mounting frame). The glass mounting devices 102 are arranged and assembled to press the sight glass 206 against the light-absorbing seal.

An exemplary implementation of the fluid mounting device 110 includes a hose nozzle as a hose connection 210. The hose connection 210 protrudes from the inner part 104 in the opposite direction to the sensing direction 501 and includes a cavity (also referred to as a connection cavity) which provides a section of the inner fluid transfer channel 106 or is adjacent to it. The hose connection 210 may, for example, be monolithically connected to the inner part 104, but this is not necessarily the case (e.g., if it is screwed in). By the hose connection 210 (e.g., its connection cavity), a first hose 210s (also referred to as an inner hose) may be fluidically coupled to the inner part 104 and/or the inner fluid channel 106 during operation. The hose connection 210 can, for example, be inserted into the inner hose.

The or an alternative exemplary implementation of the fluid assembly device 110 (preferably according to example 6) includes a flange 214 into which the inner and/or outer fluid transfer channel 106, 116 opens. The flange 214 has, for example, a through-opening into which the hose connection 210 protrudes. It may be understood that the hose connection 210 may optionally also protrude from the flange 214, which may facilitate assembly.

To facilitate assembly, the fluid assembly device 110 may have a tubular intermediate piece 216, the end face of which facing away from the inner part 104 includes the flange 214. An exemplary implementation of the intermediate piece 216 includes a first sealing device facing the inner part 104 and/or a second sealing device facing the outer part 102, which, for example, has a sealing groove and a ring seal received therein. The first sealing device (e.g., the ring seal) may bear against the inner part 104 (e.g., a flange thereof) during operation when the intermediate piece 216 is attached thereto. Alternatively, or additionally, the second sealing device (e.g., the ring seal) may bear against the outer part 102 (e.g., a flange thereof) during operation when the intermediate piece 216 is attached thereto.

An exemplary implementation of the inner hose is arranged in a second hose 220s (also referred to as the outer hose), which is connected to the flange 214, e.g., by a clamp or other clamping ring.

In the event that the camera mounting device 204, e.g., its mounting sleeve, impedes fluid exchange too much, the inner part 104 may have a third fluid channel 120 (also referred to as an overflow or bypass channel) which connects two sections of the receiving space (e.g., in the overflow section 102h) between which the camera holding device 204 is arranged.

An exemplary implementation of the cover flap 122 (preferably according to example 15) includes an aperture and is rotatably mounted. The cover flap 122 may be rotated into a first state (also referred to as the closed state) in which it covers the light-receiving region. The cover flap 122 may be rotated into a second state (also referred to as the open state), in which the light-receiving region is exposed. Furthermore, the cover flap 122 is coupled to a spring 124. The spring is configured to press the cover flap 122 against the overpressure housing 150 and/or to provide at least a restoring force that counteracts rotation of the cover flap 122 out of the closed position.

An exemplary implementation of the transmission (preferably according to example 16) includes a Bowden cable 126 and/or a lever 128. The Bowden cable 126 may be coupled to the cover flap 122 by the lever 128, so that a force transmitted to the Bowden cable 126 is converted into a torque which causes the cover flap 122 to rotate out of the open state.

FIG. 2B illustrates the detection system according to various embodiments 200b in a schematic view when the cover flap 122 is brought into the open state, e.g., configured according to embodiments 200a and/or according to example 17.

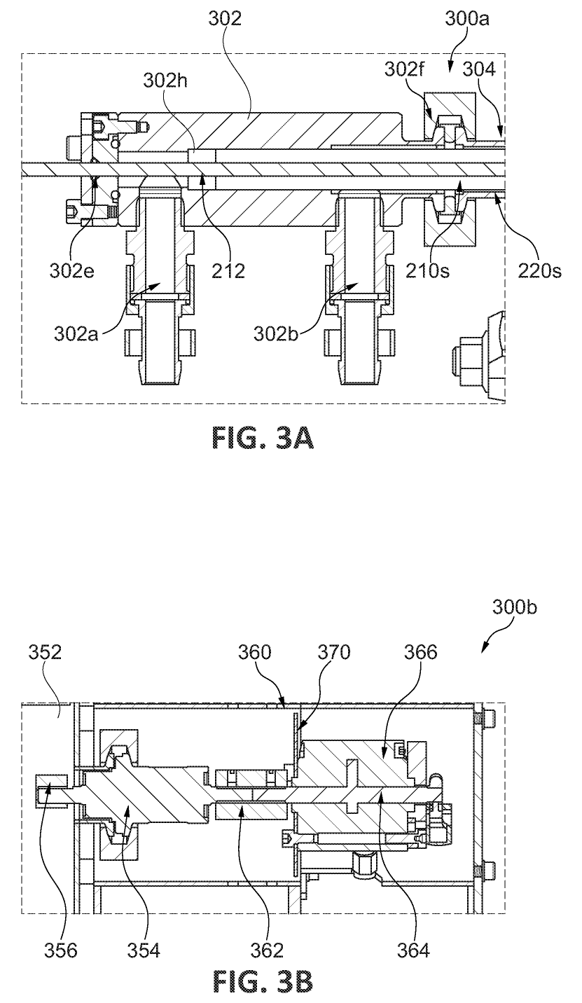

FIG. 3A illustrates a supply system of the detection system according to various embodiments 300a in a schematic cross-sectional view, which may be or become coupled to the protection device, e.g., configured according to one of the embodiments 100a to 200b and/or according to Example 1.

The supply system includes a hose system 304 comprising the outer hose 220s and the inner hose 210s arranged therein. Furthermore, the supply system includes an end piece 302, which includes a first fluid connection 302a (also referred to as a return connection) and a second fluid connection 302b (also referred to as a flow connection) and may be coupled to the hose system 304. The first fluid connection 302a is then fluidically coupled to the receiving chamber by the inner tube 210s. The second fluid connection 302b is then fluidically coupled to the receiving chamber by the outer tube 220s.

An exemplary implementation of the end piece 302 includes a flange which is coupled to the outer hose 220s, e.g., by a clamp or another clamping ring. Furthermore, the end piece 302 includes a cavity 302h into which the inner hose 210s protrudes.

On a side opposite the flange 302f, the end piece 302 includes a cable passage 302e, which delimits the cavity and is configured to receive the cable 312, which is arranged in the inner hose 210s. The cable 312 is led out of the end piece 302 by the cable passage 302e (e.g., through a through-opening thereof). Furthermore, the cable passage 302e includes a seal which presses against the cable 212 so that the cable passage 302e is fluid tight.

FIG. 3B illustrates a vacuum assembly according to various embodiments 300b (e.g., according to Example 22) in a schematic cross-sectional view, which comprises the protection device, e.g., configured according to one of embodiments 100a to 300a and/or according to Example 1.

The vacuum arrangement includes a vacuum chamber which includes a chamber wall 352 on which a rotary feedthrough 354 is mounted. Furthermore, the vacuum arrangement includes a drive device 360 which is coupled to the Bowden cable by the rotary feedthrough 354. The drive device 360 is configured to transmit a force to the Bowden cable by the rotary feedthrough 354.

An exemplary implementation of the rotary feedthrough 354 is coupled to the Bowden cable by a lever 356.

An exemplary implementation of the drive device 360 includes a rotatably mounted shaft 364 and a shaft coupling 362, which couples the shaft 364 to the rotary feedthrough 354. Furthermore, the drive device 360 includes a torque source 366, which may, for example, comprise a pneumatic rotary drive and is configured to transmit torque to the shaft 364 to be transferred to the rotary feedthrough 354. For this purpose, the torque source 366 may, for example, be supported on the vacuum chamber in a rotationally secured manner by a torque support 370.

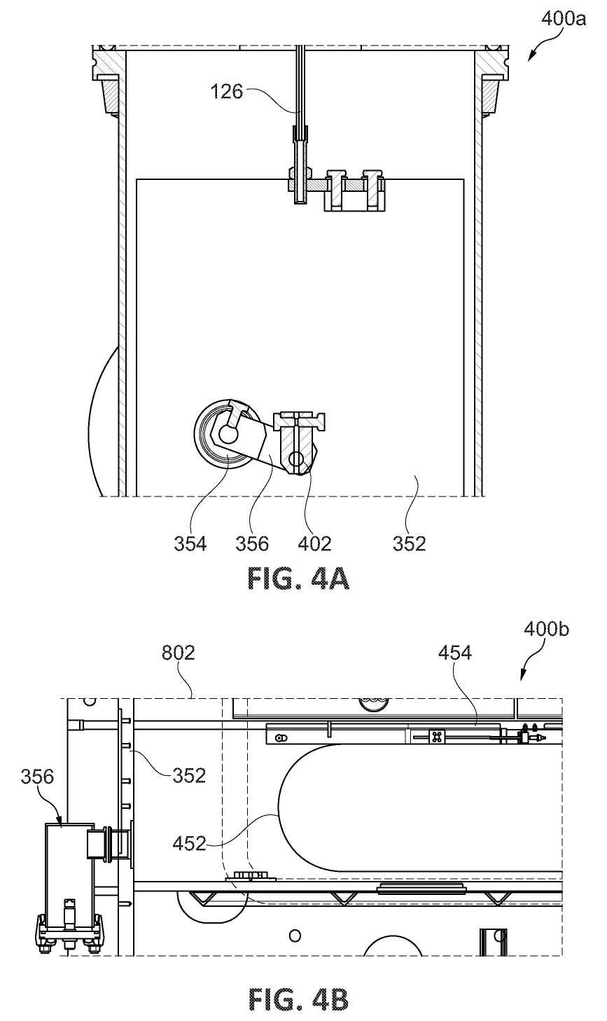

FIG. 4A illustrates the vacuum arrangement (e.g., according to Example 22) according to various embodiments 400a in a schematic side view looking at the chamber wall 352, which includes the protection device, e.g., configured according to one of embodiments 100a to 300b and/or according to Example 1. The Bowden cable 126 may be coupled to lever 356 by a Bowden cable clamp 402.

FIG. 4B illustrates the vacuum arrangement (e.g., according to example 22) according to various embodiments 400b in a schematic cross-sectional view along a transport direction, which includes the protection device, e.g., configured according to embodiments 400a and/or according to example 1. The vacuum arrangement includes a transport device (not shown) for transporting a substrate along the transport direction through a substrate transfer opening 452 of the vacuum chamber 802. The sensing direction 501 (not shown) may be directed toward the substrate transfer opening 452, which makes it possible to monitor whether a substrate is located in the substrate transfer opening.

In general, this area of the vacuum chamber near the substrate transfer opening 452 is difficult to access, for example, for a monitoring process based on image information of the substrate transfer opening 452. This is facilitated according to various embodiments.

Optionally, the vacuum assembly may include a light source 454 that is configured to emit light toward the substrate transfer opening. The light source 454 may, for example, be disposed above the substrate transfer opening.

An exemplary implementation of the light source 454 includes a ceramic socket and a heat-resistant (i.e., resistant to the operating temperature) incandescent lamp (e.g., oven lamp) received therein. The heat-resistant incandescent lamp is coupled to an electrical feedthrough 356 by an electrical cable having heat-resistant insulation (e.g., glass fiber insulation), by which electrical power may be supplied to the light source 454.

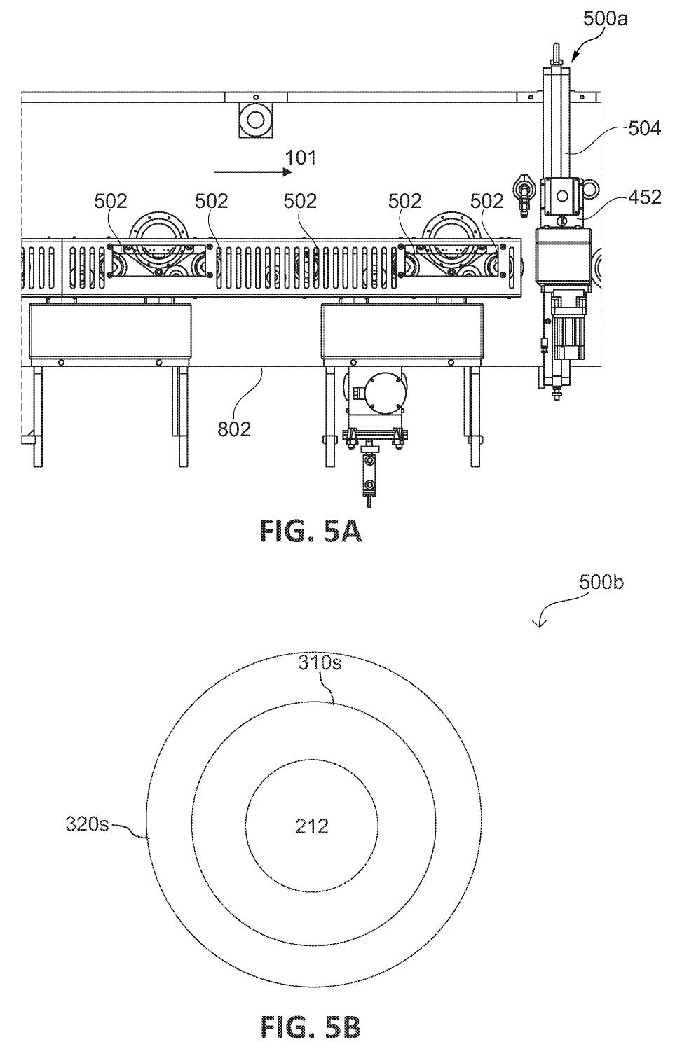

FIG. 5A illustrates the vacuum arrangement (e.g., according to Example 22) according to various embodiments 500b in a schematic side view with a view transverse to the transport direction 101, which includes the protection device, e.g., configured according to one of the embodiments 100a to 400b and/or according to Example 1. The transport device includes a plurality of transport rollers 502. The vacuum chamber includes a valve flap 504, by which the substrate transfer opening 452 may be closed (e.g., vacuum-tight), on which the sensing direction 501 (not shown) is directed.

FIG. 5B illustrates a hose system according to various embodiments 500b in a schematic cross-sectional view, which is coupled to the mounting device of the protection device, which is configured according to one of the embodiments 100a to 500a and/or according to example 1. The hose system comprises the outer hose 320s and the inner hose 310s arranged therein. The cable 212 may be arranged in the inner hose. During operation, the outer hose 320s and the inner hose 310s arranged therein may exchange a fluid (e.g., a cooling liquid) with each other, e.g., by the receiving space and/or by the overflow section 102h.

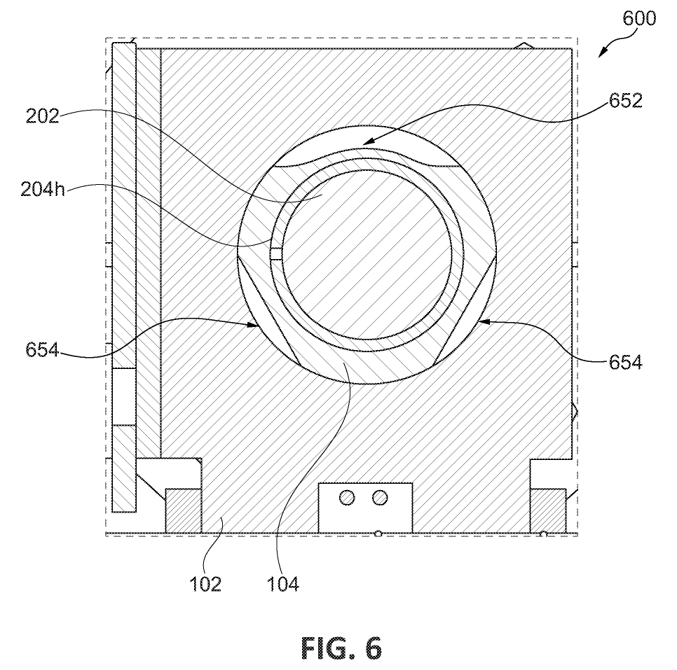

FIG. 6 illustrates a protection device according to various embodiments 600 in a schematic side view looking along the sensing direction 501, which includes the protection device, e.g., configured according to one of the embodiments 100a to 500b and/or according to example 1. Shown are a tubular holding device 204h, a cylindrical camera 202 in the holding device 204h, and the inner part 104, which includes several channel-shaped recesses for providing one or more fluid transfer channels, of which a first recess 652 provides the overflow and each of two second recesses 654 provides an outer fluid transfer channel 116.

In the event that the sensing device itself is not waterproof and/or at least configured for operation in water as a fluid, a water-free (or low-water) cooling fluid (e.g., an oil, alcohol, and/or a gas) may be used as a fluid and/or an enclosure, which is explained below.

An exemplary implementation of the enclosure is configured to provide a hermetically separated and/or dry interior space (also referred to as an intermediate space), for example, when the fluid is liquid (e.g., a cooling fluid) and contains water. This increases the service life of a sensing device, for example, if it is not waterproof itself or does not have its own encapsulation. If the enclosure is present, the holding device 204 may be configured to hold the enclosure.

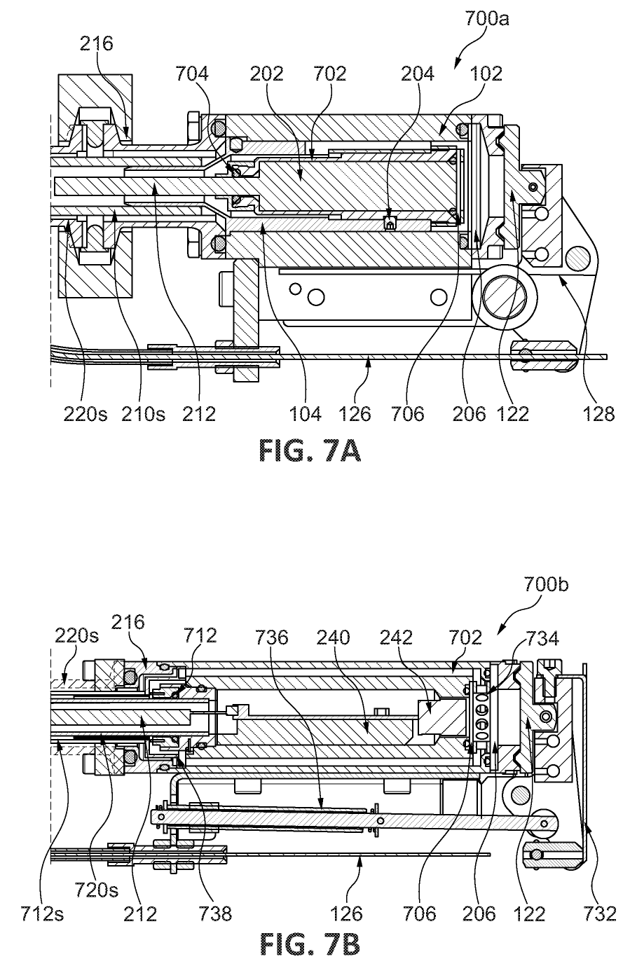

FIG. 7A illustrates a detection system according to various embodiments 700a in a schematic side view or cross-sectional view, which includes the enclosure 702, e.g., according to one of the embodiments 100a to 600 and/or according to example 31.

An exemplary implementation of the enclosure 702 includes several (e.g., interlocking) housing components (also referred to as third housing components or enclosure parts), which are configured, for example, to be joined together in a fluid-tight (e.g., watertight) manner. The enclosure parts have a first enclosure part which includes a light-receiving wall 706 (also referred to as an inner light-receiving wall) on its front side or is at least configured so that an additional sight glass 706 (also referred to as an inner sight glass), e.g., as an enclosure part, may be mounted on it. The enclosure parts have a second enclosure part which includes or may receive a cable feed-through 704 which, for example, faces away from the light-receiving region.

The camera 202 (e.g., in a form-fitting manner) and, optionally, a gas may be received inside the housing 702 (also referred to as an intermediate space), e.g., if the housing 702 is mounted in the atmosphere. It may be understood that the gas may comprise or consist of at least atmospheric air but may also have a different chemical composition if required, e.g., it may consist of nitrogen or dry air.

An exemplary implementation of the cable entry 704 includes a ring seal that bounds a passage opening (also referred to as a cable opening) of the cable entry 704, and a form-fit mechanism that is configured to be actuated (e.g., rotated) in response to pressing the ring seal against a cable disposed in the cable opening. This configuration guides the cable.

An exemplary implementation of the inner sight glass provides at least a portion of the inner light-receiving wall 706 and may, for example, include a glass plate. An exemplary implementation of the inner light-receiving wall 706 is provided at least in sections by the inner sight glass. The inner sight glass may be received in a form-fitting manner in a recess formed between two mounting devices of the housing (also referred to as inner glass mounting devices), which form, for example, an inner frame (e.g., mounting frame). The inner glass mounting devices are configured and assembled to press the inner sight glass against a light-receiving seal of the housing.

FIG. 7B illustrates the detection system according to various embodiments 700b in a schematic view when the cover flap 122 is brought into the open state, e.g., according to one of embodiments 100a to 700a and/or according to example 31.

In contrast to embodiments 700a, enclosure 702 includes a hose connection 712 (also referred to as an inner hose connection), e.g., a hose nozzle, instead of cable feedthrough 704. The inner hose connection 712 is configured so that a hose 712s (also referred to as an intermediate hose 712s) may be mounted on it, which is fluidically coupled to the intermediate space. For example, the inner hose connection 712 includes a cavity (also referred to as a connection cavity) into which the intermediate hose 712s may be or will be inserted. The inner hose connection 712 can, for example, be monolithically connected to the second housing component, but this is not necessarily the case (e.g., if it is screwed in). By the inner hose connection 712 (e.g., its connection cavity), the intermediate hose 712s may be fluidically coupled to the intermediate space during operation.

An exemplary implementation of the housing 702, e.g., of the first housing component thereof, includes one or more overflow holes as a fluid channel, which couples two sections of the receiving space (e.g., in the overflow section 102h), between which the holding device 204 is arranged, with each other.

An exemplary implementation of the sensing device (e.g., according to Example 34) includes a rigid carrier on which a printed circuit board is mounted. The printed circuit board includes a circuit that is configured to mediate communication between the cable 212 and the sensor 242.

An exemplary implementation of the protection device further comprises a shield (e.g., radiation shield) comprising one or more shield walls and/or in which the overpressure housing is arranged. A shielding wall 732 of the shielding may, for example, be coupled as a shielding cover 732 (e.g., protective plate 732) and/or with the cover flap 122 (e.g., rigid).

An exemplary implementation of the inner sight glass 706 is held by a (e.g., annular) spacer 734 and/or coupled to the outer sight glass 206. For example, a force may be transmitted from the outer sight glass 206 to the inner sight glass 706 by the spacer 734, by which, for example, the inner sight glass 706 is pressed against a sealing device. This simplifies the design. Optionally, the spacer 734 may be ring-shaped and/or have a plurality of through openings which facilitate fluid exchange.

An exemplary implementation of the cover flap 122 is coupled to a spring device 736 (e.g., a compression spring) which is configured to stimulate movement of the cover flap 122 into the closed state, for example, to generate a force which stimulates the movement. Optionally (not shown), the spring device 736 may be coupled by a guide device (e.g., guide rod) to a bearing device (e.g., a pivot bearing) by which the cover flap 122 is movably mounted. The guide device ensures, for example, a straight connection between the pivot points when the cover flap 122 swivels around the pivot point of the bearing device and/or prevents the spring device from buckling.

An exemplary implementation also features an intermediate piece 738 (e.g., tubular) that facilitates water flow. The intermediate piece 738 may, for example, have a fluid connection for connecting the intermediate hose 712s and/or extend into the outer hose 220s. Alternatively or additionally, the inner hose 720s may be arranged in the intermediate piece 738. The intermediate piece 738 promotes, for example, an overflow of the cooling medium from the intermediate space formed between the outer hose 220s and the intermediate hose 712s into the supply holes and from the return holes into the intermediate space formed between the intermediate hose 712s and the inner hose 720s.

Various working examples are described below that relate to what is described herein and shown in the figures.

According to working example 1, a camera is water-cooled and electrically supplied by a hose system. This increases the range of applications, for example, to position the camera close to the processing area as a source of high temperature and/or a coating material.

According to working example 2, a sight glass is arranged in front of the camera (e.g., on the vacuum side and/or in the direction of detection) as a transparent wall. This inhibits contamination of the camera and promotes its cooling.

According to working example 3, a screen is arranged in front of the sight glass (e.g., on the vacuum side and/or in the direction of detection). The screen protects the sight glass from contamination.

According to working example 4, a camera, e.g., endoscopic, is supplied by a cable that is fed through a vacuum flange and inside a double hose into the protection device. The outer hose, e.g., a corrugated hose, provides a separation from the vacuum. The inner hose provides a separation between the supply and return of the water cooling.

According to working example 5, the camera is arranged in an overpressure housing of the protection device. There it is held and cooled by cooling water flowing around it via an overflow. A sight glass of the housing is arranged in front of the camera (e.g., in the direction of detection), which separates the cooling water from the vacuum. The sight glass allows the camera to see through to the processing area.

According to working example 6, an aperture is arranged in front of the sight glass in the direction of detection (e.g., in the direction of detection), which is opened by a Bowden cable and a lever system and closed by a spring (also referred to as a spring device).

According to working example 7, an endoscope camera is used as the camera, which includes one or more light sources (e.g., one or more light-emitting diodes) that are integrated into the housing of the endoscope camera, for example. This improves the illumination of the processing area.

According to working example 8, an additional light source is used alternatively or in addition to the light source of the camera, which is exposed to the vacuum and/or mounted on the vacuum chamber. The additional light source may, for example, comprise a low-voltage (e.g., 12 volts) halogen lamp, which is also suitable for hot environments, e.g., configured as an oven lamp. Small halogen lamps are inexpensive and suitable for vacuuming.

According to working example 9, the additional light source is operated by a temperature-resistant cable, e.g., with glass fiber insulation, and a temperature-resistant lamp holder, e.g., made of ceramic.

According to working example 10, the movement of the aperture is effected by a force (e.g., manual force) generated by a person (also referred to as manual operation) as an alternative or in addition to the drive device.

According to working example 11, the aperture is moved by an electric and/or pneumatic drive device.

According to working example 12, the protection device in which the camera is located is exposed to a vacuum, and the camera is exposed to a cooling liquid (e.g., water).

According to working example 13, the camera and/or the camera cable are water-cooled.

According to working example 14, the aperture is only opened when necessary and protects the sight glass and/or the camera from contamination.

According to working example 15, the image information provided by the camera is displayed and/or further processed at any location, e.g., at the plant control system.

The term “fluidically” in context of a coupling (e.g., fluidically coupled) is understood herein as coupling that allows the exchange of a fluid, be between the entities fluidically coupled to each other.

What is claimed is:

1. A protection device, comprising:
a first housing component and a second housing component, which are configured to be inserted into each other to form an overpressure housing in which a cavity for receiving an optical sensing device is provided, wherein the first housing member comprises a transparent light-receiving region adjacent to the cavity;
a mounting device opposite the light-receiving region for mounting one or more fluid conduits to the pressurized housing; and,
a first fluid transfer channel and a second fluid transfer channel, of which each fluid transfer channel couples the cavity to the mounting device.

2. The protection device according to claim 1, wherein the first housing component and the second housing component are tubular or comprise a tubular section.

3. The protection device according to claim 1, wherein the first housing component and the second housing component are metallic.

4. The protection device according to claim 1, wherein the second housing component is configured to be inserted into the first housing component.

5. The protection device according to claim 1, wherein the second fluid transfer channel comprises a greater extension along a direction, along which the transparent light-receiving region adjoins the cavity, than the first fluid transfer channel.

6. The protection device according to claim 1, wherein the second fluid transfer channel extends past a section of the cavity, into which the first fluid transfer channel opens.

7. The protection device according to claim 1, wherein the second fluid transfer channel is provided by a groove-shaped recess adjoining the perimeter of one or more of: the first housing component or the second housing component.

8. The protection device according to claim 1, wherein the mounting device comprises a hose connection into which the first fluid transfer channel opens and which protrudes from the second housing component.

9. The protection device according to claim 1, further comprising: a first sealing device surrounding the light-receiving region; and a transparent wall adjacent to the first sealing device.

10. The protection device according to claim 9, further comprising a clamp, by which the transparent wall is pressed against the first sealing device.

11. The protection device according to claim 1, wherein the mounting device comprises an intermediate piece which comprises a flange and a second sealing device opposite the flange for fluid-tight coupling to the overpressure housing, and wherein the first and second fluid transfer channels open into the intermediate piece.

12. The protection device according to claim 1, wherein the second housing component comprises a holding device which is configured to hold the sensing device in a rotationally secure manner.

13. The protection device according to claim 1, wherein the second housing component comprises a recess into which the first fluid transfer channel opens and which provides at least one area of the cavity.

14. The protection device according to claim 1, further comprising: a cover flap which is movably mounted so that the light-receiving region is covered by the cover flap when the cover flap is in a first state, and is exposed when the cover flap is in a first state.

15. The protection device according to claim 14, further comprising: a gear mechanism which is configured to convert a force acting on the gear mechanism into a torque and to transmit the torque to the cover flap.

16. A detection system, comprising:
the protection device according to claim 1,
the sensing device received in the cavity, wherein the sensing device comprises one or more of: a camera and an optical fiber cable.

17. The detection system according to claim 16, further comprising a hose, which coupled is by the mouting device to one or more of: the first fluid transfer channel and the second fluid transfer channel, wherein one or more of the following is disposed in the hose: an electrical cable of the sensing device and the optical fiber cable of the sensing device.

18. A method for using the detection system according to claim 16, the method comprising:
exposing the protection device to a vacuum atmosphere; and,
sensing image information by the sensing device.

19. The method according to claim 18, wherein the vacuum atmosphere, to which the protection device is exposed, comprises one or more of: a metal, a semiconductor, and a transition metal.

20. The method according to claim 18, further comprising: coating a substrate in the vacuum atmosphere by a coating process, to which the protection device is exposed.
